(19) United States
(12) Patent Application Publication
(10) Pub. No.: US 2010/0229912 A1
(43) Pub. Date: Sep. 16, 2010

(54) PHOTOVOLTAIC DEVICE THROUGH LATERAL CRYSTALLIZATION PROCESS AND FABRICATION METHOD THEREOF

(75) Inventors: Young-Joo Eo, Seocho-Gu (KR); Seh-Woh Ahn, Seocho-Gu (KR); Kwy-Ro Lee, Seocho-Gu (KR); Don-Hee Lee, Seocho-Gu (KR); Heon-Min Lee, Seocho-gu (KR)

Correspondence Address: BIRCH STEWART KOLASCH & BIRCH, PO BOX 747, FALLS CHURCH, VA, 22040-0747, US

(73) Assignee: LG ELECTRONICS INC., Seoul (KR)

(21) Appl. No.: 12/293,749

(22) PCT Filed: Jan. 22, 2008
(86) PCT No.: PCT/KR2008/000399

§ 371 Date: Sep. 19, 2008

(30) Foreign Application Priority Data
Jan. 23, 2007 (KR) 10-2007-0007198

(51) Int. Cl. H01L 31/042; H01L 31/18

(52) U.S. Cl. 136/244; 438/73; 257/E31.043; 257/E31.047

(57) ABSTRACT

The present invention relates to a photovoltaic device through a lateral crystallization process and a fabrication method thereof, and in particular to a high efficiency solar cell module and a fabrication method thereof.

The present invention comprises a first solar cell having an amorphous silicon layer formed on a first substrate, a second solar cell having a microcrystalline silicon semiconductor layer formed on a second substrate, and a junction layer junctioning the first solar cell and the second solar cell, making it possible to obtain a solar cell with high efficiency, low fabricating costs, high product characteristic, and high reliability.

### TECHNICAL FIELD

The present invention relates to a photovoltaic device, and in particularly to a solar cell module and a fabrication method thereof. More specifically, the present invention provides a solar cell module having a structure including an amorphous silicon semiconductor layer and a microcrystalline silicon semiconductor layer, the structure being formed through a step forming the amorphous silicon semiconductor layer and the semiconductor layer having the microcrystalline silicon crystallized from the amorphous silicon, respectively, provided on a substrate and then junctioning them.

### BACKGROUND ART

Generally, a solar cell, which is a photovoltaic device, is a clean energy source producing energy by converting light energy transferred from the sun to the earth into electric energy. Many studies on the solar cell have been progressed for decades. Since photovoltaic power generation using the solar cell, etc. does not cause environmental destruction by using renewable energy and can obtain the energy source anywhere, the study thereon as a next generation clean energy source has been actively progressed. Today, a use of a Si single crystal solar cell that has been widely commercialized for the photovoltaic power generation is restricted due to high fabricating costs caused by using a high expensive wafer. Various attempts to develop a thin film type solar cell capable of solving the problem and reducing raw material prices as well as obtaining high efficiency and high reliability have been proposed and studied.

A commercialized method for fabricating the solar cell using a conventional silicon thin film technology fabricates the solar cell by sequentially stacking a transparent electrode, amorphous silicon p-i-n layers, a transparent electrode, and a metal electrode.

However, as can be appreciated from FIG. 2 that is a graph showing light absorption coefficients according to the wavelengths of the silicon thin film for each particle state, since the absorption coefficient in an infrared region of the amorphous silicon is lower than that of the crystalline silicon or the microcrystalline silicon so that the efficiency of the solar cell is low, many studies have been attempted to increase the efficiency when the thin film type solar cell uses the amorphous silicon. The following methods have been generally proposed and attempted.

1) A method of fabricating a double junction solar cell by performing the duplicate deposition of the amorphous silicon p-i-n layers.

2) A method of fabricating a double junction solar cell by depositing materials (for example, SiGe) with different absorption bands in an incident natural light wavelength underneath the amorphous silicon thin film.

3) A method of fabricating a double junction solar cell by further depositing the microcrystalline silicon layer with different light wavelength absorption bands and with the same material as the amorphous silicon.

4) A method of fabricating at least triple junction solar cell using at least two kinds of materials with different light wavelength absorption bands.

The most widely used method is a number 3) technology. The product from Kaneka and Mitsubishi Heavy Industry (MHI), Japan is on the market.

FIG. 1 schematically shows a structure of a solar cell fabricated through a method of fabricating the solar cell using number 3) technology.

Referring to FIG. 1, a conventional solar cell is characterized in that a transparent electrode layer 102 made of SnO2:F or ZnO:Al, etc. is deposited on a transparent glass substrate 101 and amorphous silicon semiconductor layers 103, 104, and 105 and microcrystalline silicon semiconductor layers 107, 108, and 109 are junction in sequence of p-i-n layers. An intermediate transparent electrode layer 106 may be deposited between the amorphous silicon semiconductor layer and the microcrystalline silicon semiconductor layer and after stacking an upper semiconductor layer, a rear transparent electrode layer 110 and a metal electrode layer 111 that may be made of aluminum, silver, etc., are sequentially deposited.

The conventional fabrication method for manufacturing the solar cell such as FIG. 1 is shown as a stacked structure of a solar cell module according to the fabrication process of FIG. 3.

Referring to FIG. 3, a transparent electrode layer (TC0) 302 is stacked on a glass substrate 301 and amorphous silicon semiconductor p-type 303, i-type 304, and n-type 305 are sequentially stacked thereon. Subsequently, an intermediate transparent electrode layer 306 is provided and crystalline silicon semiconductor p-type 307, i-type 308, and n-type 309 are deposited thereon, and a rear transparent electrode layer 310 and a back panel 311 are formed by means of a lamination process.

However, such a deposition method, in particular a method of directly depositing the microcrystalline silicon layer using a chemical vapor deposition (CVD) has a disadvantage that the processing time is very long.

Also, since the solar cell module fabricated by the method of FIG. 3, that is, the conventional thin film type silicon stacked solar cell is a serial connection structure, there is a problem in that current generated by light is restricted by means of the solar cell less generating current among the two solar cells. Therefore, in order to achieve high efficiency, there is a difficulty in a design and fabrication to make the two solar cells generate the same optic current.

Generally, when depositing the microcrystalline silicon layer, since a large amount of silane gas (SiH₄) used as a raw material is diluted with hydrogen and is deposited, a film forming rate is very slow.

Also, since alternating current frequency used upon forming plasma is very high, that is, 40 MHz or more so that a structure of an electrode and a chamber is different from a structure using an existing RF (13.56 MHz), it is difficult to fabricate a film forming apparatus. Therefore, a need exists for a new process technology.

### DISCLOSURE

### Technical Problem

Therefore, it is an object of the present invention to provide a solar cell module having a structure including an amorphous silicon semiconductor layer and a microcrystalline silicon semiconductor layer, the structure being formed through a step forming the amorphous silicon semiconductor layer and the semiconductor layer having the microcrystalline silicon crystallized from the amorphous silicon, respectively, provided on a substrate and then junctioning them.

### Technical Solution

In order to accomplish the object, there is provided a photovoltaic device of the present invention comprising a first solar cell having an amorphous silicon layer formed on a first substrate; a second solar cell having a microcrystalline silicon semiconductor layer formed on a second substrate; and a junction layer junctioning the first solar cell and the second solar cell.

In the present invention, a structure of the amorphous silicon semiconductor layer and the microcrystalline silicon semiconductor layer is not particularly limited, however, may preferably be a structure stacked in sequence of p layer-i layer-n layer.

In the present invention, the first solar cell may comprise a first transparent electrode layer, an amorphous silicon p-type semiconductor layer, an amorphous silicon i-type semiconductor layer, an amorphous silicon n-type semiconductor layer, and a second transparent electrode layer on the first substrate.

Also, the second solar cell may comprise a third electrode layer, an n-type semiconductor layer, an i-type semiconductor layer, a p-type semiconductor layer, and a fourth transparent electrode layer on the second substrate.

The n-type semiconductor layer, i-type semiconductor layer, and p-type semiconductor layer of the second solar cell may be the microcrystalline silicon semiconductor layer. In other words, all the semiconductor layers of the second solar cell may be made of the microcrystalline silicon and only at least one semiconductor layer of the second solar cell may be made of the microcrystalline silicon.

The n-type semiconductor layer, i-type semiconductor layer, and p-type semiconductor layer of the second solar cell are a lateral crystallization layer, wherein all the semiconductor layers of the second solar layer may be the lateral crystallization layer and only at least one semiconductor layer of the second solar layer may be the lateral crystallization layer. This lateral crystallization layer may be obtained by deriving the lateral crystallization from the amorphous silicon.

The third electrode layer may be formed of a metal electrode or a metal electrode and a transparent electrode. The third electrode layer may be configured of only the metal electrode layer, however, may preferably increase the amount of light introduced into a solar cell layer by inserting the transparent electrode layer between the metal electrode layer and the semiconductor layer of the solar cell.

In the present invention, the second transparent electrode layer and the fourth transparent electrode layer may be connected by means of the junction layer. Since the second transparent electrode layer of the first solar cell and the fourth transparent electrode layer of the second solar cell are connected putting the junction layer therebetween, the present invention has a form where the second solar cell is formed on the upper portion of the first solar cell in a reverse stacking sequence. Therefore, the second substrate of the second solar cell will be served as a back panel substrate in the overall photovoltaic device.

In the present invention, the junction layer may comprise a transparent adhesive.

In the present invention, the first substrate and the second substrate may be a transparent substrate and their materials are not limited. The transparent substrate may be made of transparent materials and preferably may be a glass substrate.

In the present invention, the first solar cell and the second solar cell are electrically connected and may be connected in series or in parallel.

In order to accomplish the object, there is provided a fabrication method of a photovoltaic device of the present invention comprising the steps of forming an amorphous silicon semiconductor layer and forming a semiconductor layer including microcrystalline silicon made by crystallization of the amorphous silicon semiconductor layer.

Also, in order to accomplish the object, there is provided a fabrication method of a photovoltaic device according to another embodiment of the present invention comprising the steps of forming a first solar cell having an amorphous silicon semiconductor layer on a first substrate; forming a second solar cell having a microcrystalline silicon semiconductor layer on a second substrate and electrically connecting the first solar cell and the second solar cell by a junction thereof.

The electrical connection of the two solar cells may be a serial connection and a parallel connection.

In the present invention, the step of forming the first solar cell sequentially stacks a first transparent electrode layer, an amorphous silicon p-type semiconductor layer, an amorphous silicon i-type semiconductor layer, an amorphous silicon n-type semiconductor layer, and a second transparent electrode layer on the first substrate.

Also, the step of forming the second solar cell sequentially stacks a third electrode layer, a microcrystalline silicon n-type semiconductor layer, a microcrystalline silicon i-type semiconductor layer, a microcrystalline silicon p-type semiconductor layer, and a fourth transparent electrode layer on the second substrate.

The microcrystalline silicon semiconductor layer is made of the microcrystalline silicon by forming the amorphous silicon semiconductor layer and then crystallizing it.

In the present invention, the crystallization method may be any one selected from a group consisting of an excimer laser annealing (ELA), a sequential lateral solidification (SLS), a solid phase crystallization (SPC), a metal induced crystallization (MIC), a metal induced lateral crystallization (MILC), a super grain silicon (SGS), a field enhanced-rapid thermal annealing process (FE-RTP), and a continuous grain silicon (CGS) methods.

In the present invention, the third electrode layer may be formed of a metal electrode or a metal electrode and a transparent electrode. The third electrode layer may be formed of one metal electrode layer or formed to be separated into the metal electrode layer and the transparent electrode layer. When the third electrode layer is formed to be separated into two layers, it is preferable that the semiconductor layer of the second solar cell is formed and then, the transparent electrode layer and the metal electrode layer are stacked in sequence.

In the present invention, the second transparent electrode layer and the fourth electrode layer may be junctioned by means of a transparent adhesive.

With the junction, a structure that the first solar cell may be stacked on the second solar cell, and vice versa may be made.

In the present invention, the semiconductor layer of the second solar cell may be the microcrystalline silicon semiconductor layer or the microcrystalline silicon semiconductor layer crystallized from the amorphous silicon.

In the present invention, the crystalline size crystallized in the amorphous silicon is not necessarily limited, but is preferably the microcrystalline and may be grown to the crystalline silicon.

In the present invention, the semiconductor layer having the amorphous silicon semiconductor layer and the microcrystalline silicon is preferably stacked in sequence of p layer-i layer-n layer and the microcrystalline silicon may be obtained by the lateral crystallization process of the amorphous silicon.

The module structure of the photovoltaic device of the present invention is only one example and is not necessarily limited thereto.

### Advantageous Effects

With the present invention as described above, it has an effect of providing a fabrication method of a customized silicon-based thin film type solar cell capable of reducing fabricating costs by shortening processing time and achieving automation due to a simple fabrication as compared to the fabrication method of the conventional silicon stacked solar cell.

Also, the present invention has an effect of providing an economically higher value addition since the silicon-based thin film solar cell of the present invention can be widely spread and utilized in various industrial fields such as construction materials, and the like, such as a roof or a window of a home or a public house, a house for agriculture, etc.

### DESCRIPTION OF DRAWINGS

The above and other objects, features, and advantages of the invention will be more apparent from the following description taken in conjunction with the accompanying drawings, in which:

FIG. 1 is a cross sectional view showing a structure of a tandem type silicon thin film type solar cell according to one embodiment of the prior art.

FIG. 2 is a graph showing light absorption coefficients according to the wavelengths of the silicon thin film for each particle state.

FIG. 3 is a cross sectional view showing a stacked structure of the silicon thin film type solar cell module and a fabrication process according to one embodiment of the prior art.

FIGS. 4 to 17 are cross sectional views showing stacked structures of the silicon thin film type solar cell module and fabrication processes according to one embodiment of the present invention.

FIG. 18 is a cross sectional view showing a 4-terminal wiring structure of the thin film type silicon solar cell according to one embodiment of the present invention.

FIG. 19 is a current-voltage characteristic curve of an amorphous and microcrystalline silicon tandem type cell according to one embodiment of the prior art.

FIG. 20 is a current-voltage data table of the amorphous and microcrystalline silicon tandem type cell of FIG. 19.

FIG. 21 is a current-voltage characteristic curve of an amorphous and microcrystalline silicon tandem type cell according to one embodiment of the present invention.

FIG. 22 is a current-voltage data table of the amorphous and microcrystalline silicon tandem type cell of FIG. 21.

FIG. 23 is a cross sectional view showing a serial connection structure of a thin film type silicon solar cell module according to one embodiment of the present invention.

FIG. 24 is a cross sectional view showing a parallel connection structure of a thin film type silicon solar cell module according to one embodiment of the present invention.

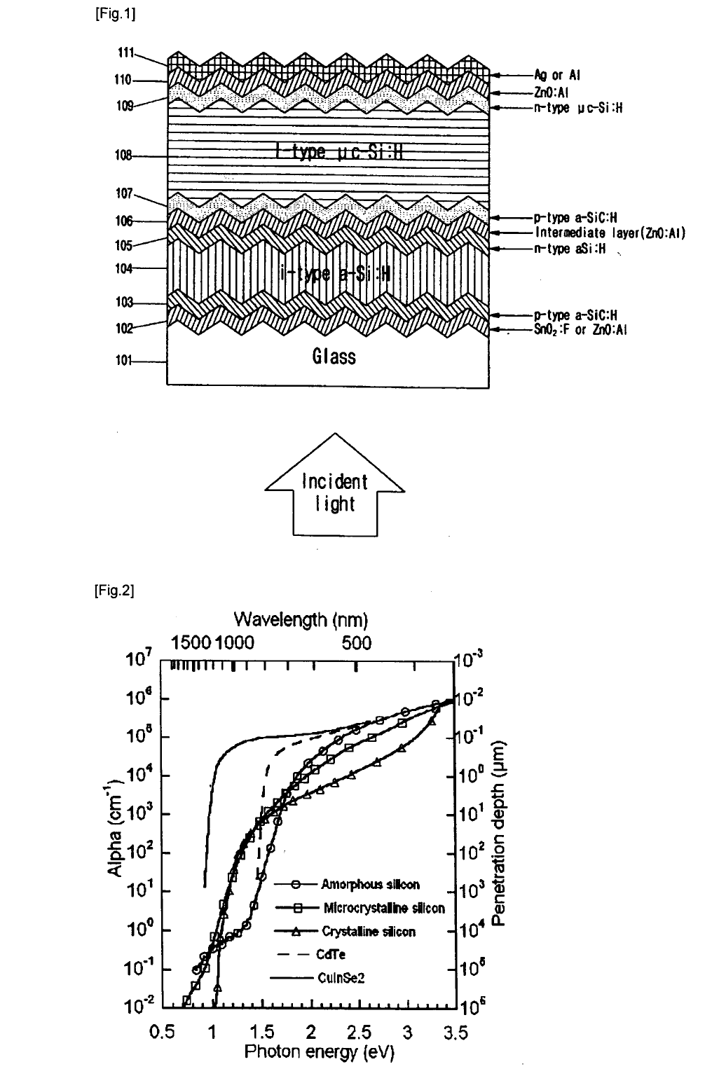

### DESCRIPTION FOR KEY ELEMENTS IN THE DRAWINGS

101,301,401,501,801,901: Glass substrate

102,302,402,502,802,902: Transparent electrode layer

103,303,403,503,803,903: Amorphous silicon semiconductor p layer

104,304,404,408a,504,804,904: Amorphous silicon semiconductor i layer

105,305,405,505,805,905: Amorphous silicon semiconductor n layer

106,306,406,506,806,906: Transparent electrode layer

107,307,407,507,807,907: Microcrystalline silicon semiconductor p layer

108,308,408b,508b,808b,908b: Microcrystalline silicon semiconductor i layer

109,309,409,509,809,909: Microcrystalline silicon semiconductor n layer

110,310,410,510,810,910: Transparent electrode layer

111: Metal electrode layer

311,411,511,811,911: Back panel substrate

412,512,812,912: Transparent adhesive cl BEST MODE

Hereinafter, the embodiments of the present invention will be described with reference to the accompanying drawings.

In adding reference signs to the following drawings, like components will be indicated by like signs although they are shown in different drawings and the detailed description of known functions and configurations will be omitted so as not to obscure the subject of the present invention with unnecessary detail.

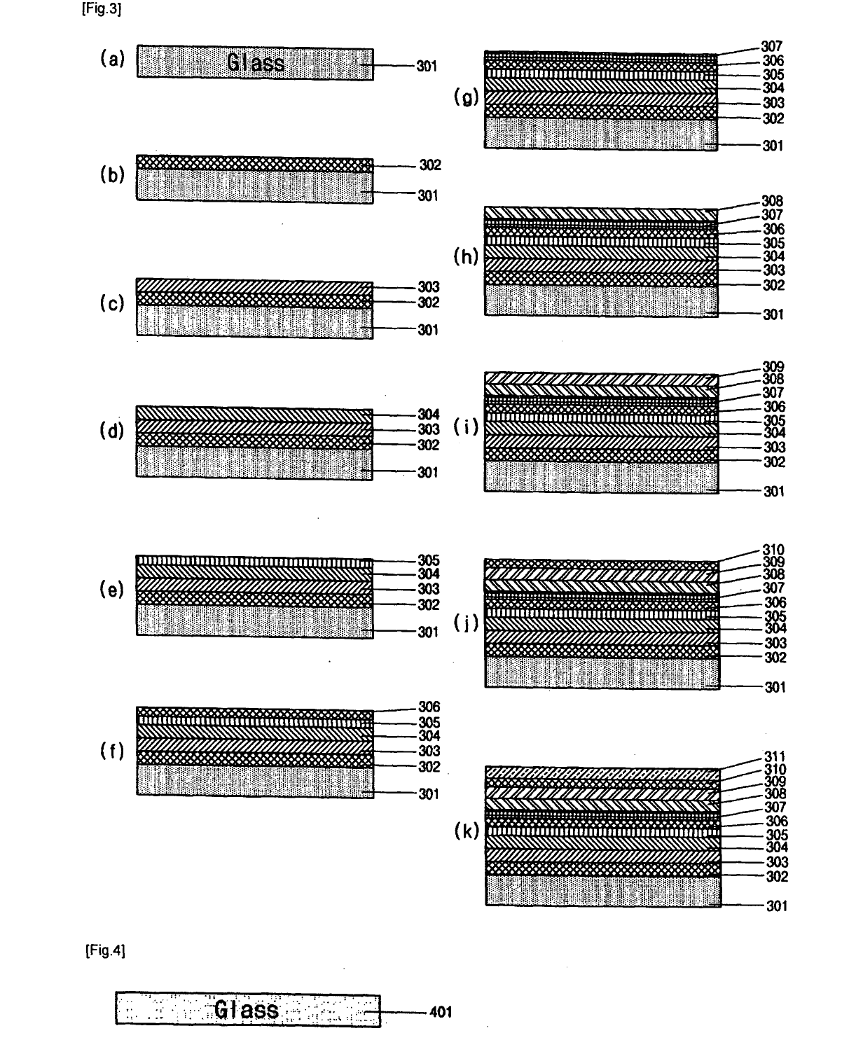

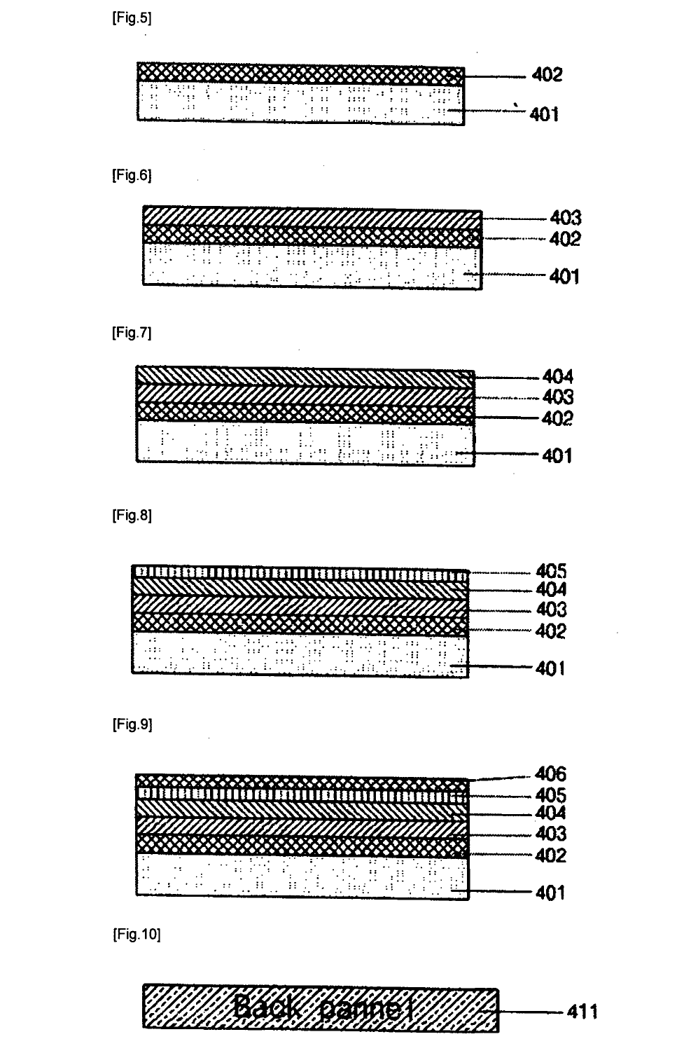

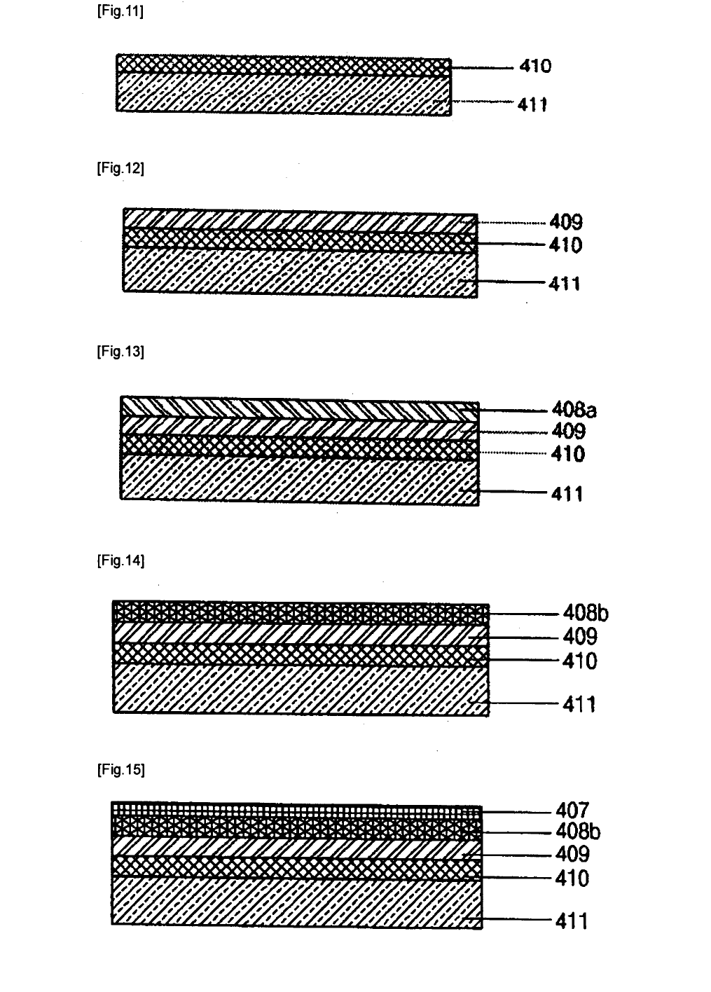

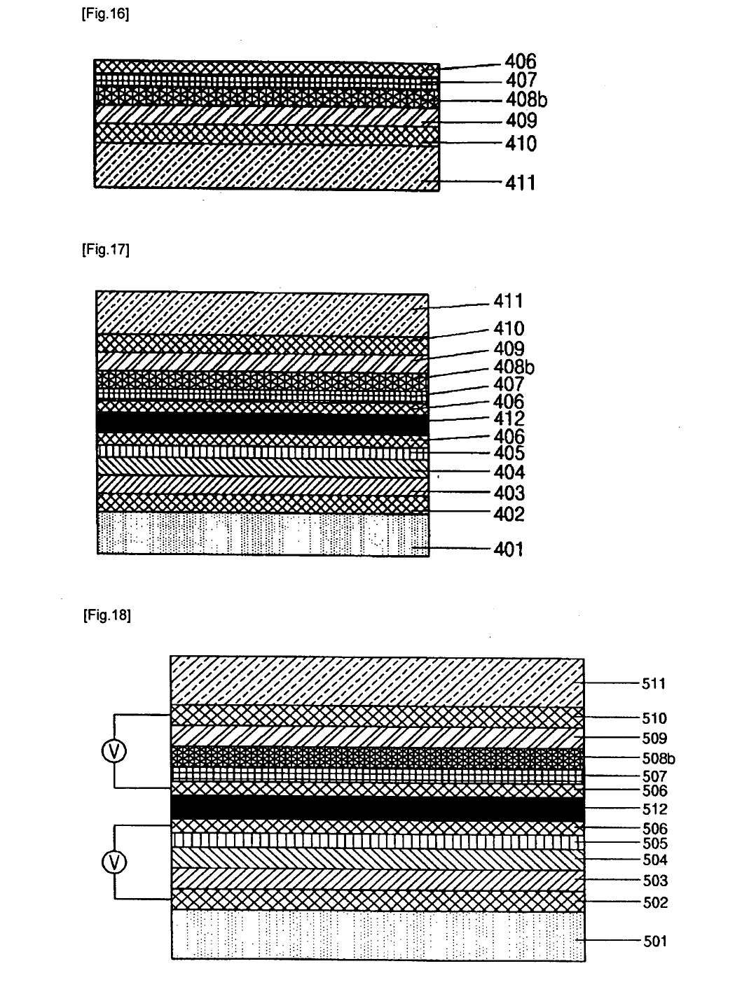

FIGS. 4 to 17 show stacked structures of a thin film type silicon solar cell module and fabrication processes thereof according to one embodiment of the present invention.

Referring to FIGS. 4 to 17, the thin film type silicon solar cell module according to one embodiment of the present invention is fabricated by junctioning a first solar cell module including an amorphous silicon semiconductor layer and a second solar cell module including a microcrystalline silicon semiconductor layer generated by crystallization of the amorphous silicon.

The first solar cell module (hereinafter, defined by a first solar cell) including the amorphous silicon semiconductor layer forms a first transparent electrode layer 402 on a glass substrate 401, and deposits a p-type 403, an i-type 404, and an n-type 405 as the amorphous silicon semiconductor layer thereon in sequence and deposits a second transparent layer 406 on the n-type 405.

On the other hand, the second solar cell module (hereinafter, defined by a second solar cell) including the semiconductor layer with the microcrystalline silicon deposits a rear transparent electrode layer 410 as a third electrode layer on a back panel substrate 411 and stacks the microcrystalline n-type silicon semiconductor layer 409 thereon. Subsequently, after stacking an amorphous silicon i-type semiconductor layer 408a, a process is performed so that the amorphous silicon i-type semiconductor can be a microcrystalline silicon semiconductor i-type 408b by means of a lateral crystallization process. After the process is performed, a microcrystalline p-type silicon semiconductor layer 407 is deposited on the microcrystalline silicon semiconductor i-type 408b and a fourth transparent electrode layer 406 is deposited thereon. A third electrode layer formed on the back panel substrate and the rear electrode layer may be configured including a metal electrode layer.

After each of the first solar cell and the second solar cell is fabricated, at least one first solar cell and at least one second solar cell are junctioned by means of a transparent adhesive 412 using the second transparent layer and the fourth transparent electrode layer as a medium.

One feature of the present invention is that the amorphous silicon solar cell is fabricated on one substrate and the microcrystalline silicon solar cell is fabricated on another substrate and the two solar cells are then junctioned. Also, in fabricating the microcrystalline silicon solar cell on the second substrate, the amorphous silicon film is formed and is then converted into the microcrystalline silicon film by a subsequent process, not directly forming the microcrystalline silicon film.

Since the electrical conductivity of the microcrystalline silicon film is increased from several ten times to several hundred times as much as the amorphous silicon film, it can be useful for obtaining the high efficiency solar cell in view of an influence by the absorption of light into the infrared region as well as the increase of conductivity.

The method converting the amorphous silicon film into the microcrystalline silicon film (low temperature polycrystalline silicon forming technology) can be sorted into laser crystallization, thermal crystallization, and composite crystallization methods. More specifically, as the laser crystallization method, there are an excimer laser annealing (ELA), a sequential lateral solidification (SLS), etc. and as the thermal crystallization method, there are a solid phase crystallization (SPC), a metal induced crystallization (MIC), a metal induced lateral crystallization (MILC), a super grain silicon (SGS), a field enhanced-rapid thermal annealing process (FE-RTP), etc., and as the composite crystallization method, there is an a continuous grain silicon (CGS).

The present invention has advantages that the processing time is shortened and the difficulties in fabricating the film forming apparatus can be avoided as well as the serial and parallel connection can be made.

In order to form a double junction in an inexpensive thin film type solar cell module, the amorphous silicon solar cell semiconductor layer and the microcrystalline silicon solar cell semiconductor layer with different light absorption bands are fabricated as a top cell and a bottom cell, respectively, as in FIG. 2. The stacked structure of the completed solar cell module can be appreciated from reference to FIGS. 4 to 7, wherein some sun light incident through glass is absorbed in the amorphous silicon semiconductor layer and the remaining light is absorbed in the lower microcrystalline silicon semiconductor layer, thereby generating photoelectron-hole pairs.

With the fabrication method of the solar cell such as FIGS. 4 to 17 of the present invention, in the case where the conventional thin film type silicon solar cell is the double junction structure, even when current of any one solar cell is less generated, the problem in the design and fabrication that make the two solar cells generate same optic current can be solved.

In order words, the present invention can easily solve the difficult problem to adjust the current-voltage characteristic between the upper semiconductor layer and the lower semiconductor layer of the double junction solar cell and can obtain higher efficiency than the existing double junction solar cell.

FIG. 18 schematically shows a four-terminal structure of the solar cell fabricated according to the present invention.

It can be appreciated from FIG. 18 that each of the first solar cell including the amorphous silicon and the second solar cell including the microcrystalline silicon is connected with two terminals by a wire. Therefore, photovoltaic is derived from the upper and lower terminals, respectively, so that the problem that the current of the any one solar cell is less generated can be solved.

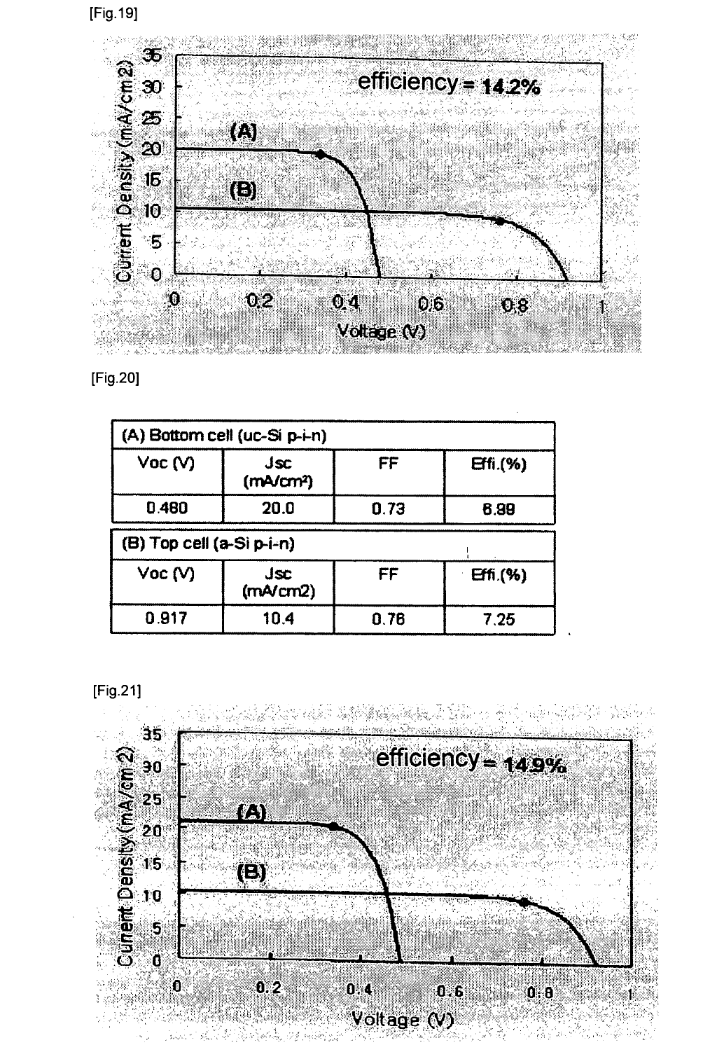

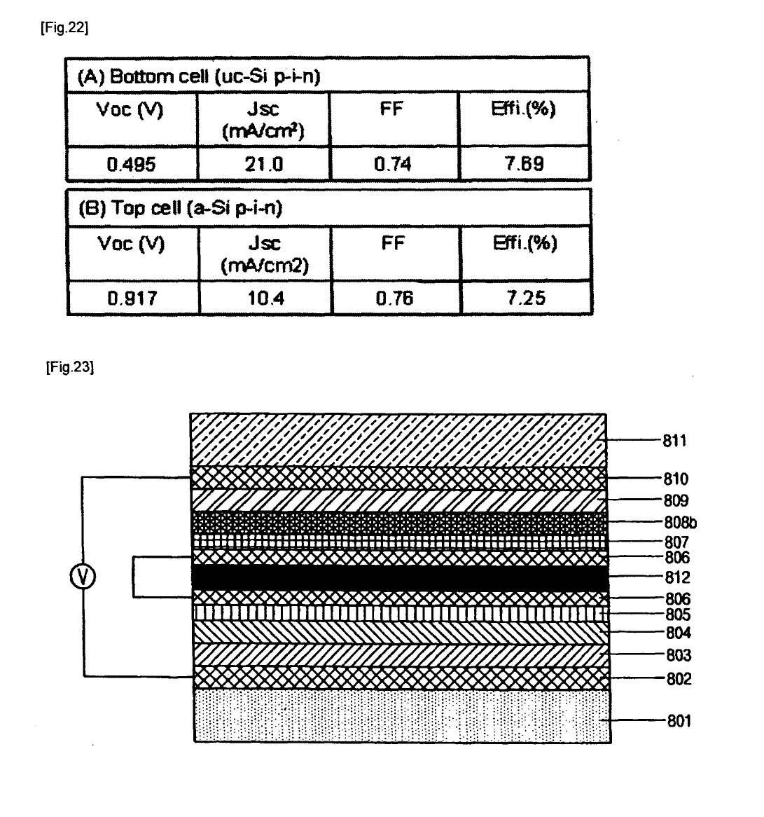

FIGS. 19 and 20 are a current-voltage characteristic curve of the amorphous and microcrystalline silicon tandem type cell and a data table thereof according to one embodiment of the prior art. FIGS. 21 and 22 are a current-voltage characteristic curve of the amorphous and microcrystalline silicon tandem type cell and a data table thereof according to one embodiment of the present invention.

As can be appreciated from the above drawings, the photovoltaic efficiency of the existing double junction solar cell and the photovoltaic efficiency of the double junction solar cell proposed by the present invention are 14.2% and 14.9%, respectively. In other words, in the thin film type amorphous silicon and the microcrystalline silicon solar cell fabricated by the existing technology, the maximum photovoltaic efficiency expectable through the efficiency of each single junction solar cell reported until now is 14.2%. To the contrary, in the four-terminal type solar cell fabricated through the structure used in the present invention, the expectable photovoltaic efficiency is 14.9%.

Referring to a table of FIG. 20, when the upper cell is fabricated using the double junction with the amorphous silicon (a-Si), it has been reported that the result is 7.25% in efficiency.

Also, when directly depositing the lower solar cell with the microcrystalline, it has been known that the efficiency is about 6.99%.

On the other hand, it can be appreciated from FIG. 22 that when the second solar cell is crystallized from the amorphous silicon and is then grown to the microcrystalline, the efficiency is increased to 7.69%.

With the fabrication method according to the present invention, since the second solar cell is obtained by the crystallization from the amorphous silicon so that the size of the microcrystalline cell particle is large, the mobility of electron-hole can be increased from at least ten times up to several hundred times as much as the directly deposited solar cell semiconductor layer. It can be expected that the efficiency is increased 10% as much as the prior art using the direct deposition.

Comparing FIGS. 19 and 20 with FIGS. 21 and 22, it can be expected that the efficiency of the double junction solar cell using the lateral crystallization process according to the present invention is more excellent than that of the existing tandem way.

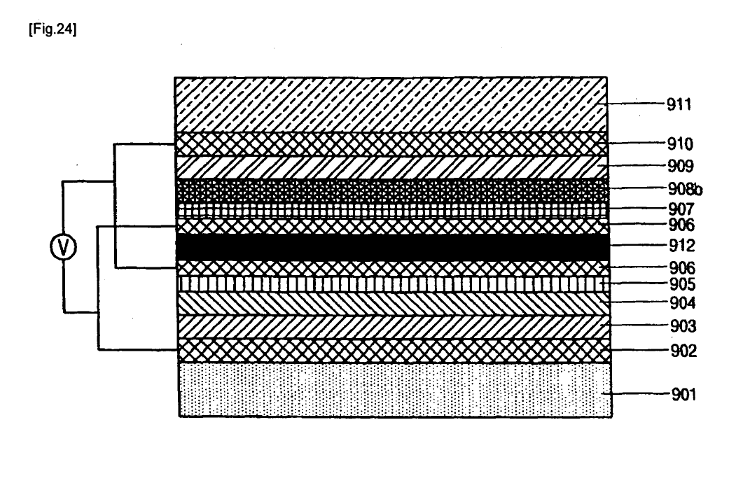

The connection method of the first solar cell and the second solar cell according to one embodiment of the present invention is shown in FIGS. 23 and 24, respectively.

Since the solar cell fabricated according to the present invention can extract the electrode individually, application fields requiring high current can use the parallel connection as shown in FIG. 24 and application fields requiring high voltage can use the serial connection as shown in FIG. 23.

Although a few embodiments of the present invention have been shown and described, it would be appreciated by those skilled in the art that changes and modifications might be made in this embodiment without departing from the principles and spirit of the invention, the scope of which is defined in the claims and their equivalents.

### INDUSTRIAL APPLICABILITY

The present invention can be used for providing a thin film type silicon stacked solar cell with high efficiency, high reliability, and low fabricating costs by improving processing time and difficulties in a fabricating process upon fabricating the conventional silicon thin film type solar cell.

Also, the present invention can provide a technology for a fabrication method of a silicon solar cell having various electrical connection forms upon fabricating a film forming apparatus of a silicon thin film.

The present invention can provide an economically higher value addition since the silicon-based thin film solar cell of the present invention can be widely spread and utilized in various industrial fields such as construction materials, and the like, such as a roof or a window of a home or a public house, a house for agriculture, etc.

1. A photovoltaic device comprising:
a first solar cell having an amorphous silicon layer formed on a first substrate;
a second solar cell having a microcrystalline silicon semiconductor layer formed on a second substrate; and
a junction layer junctioning the first solar cell and the second solar cell.

2. The photovoltaic device according to claim 1, wherein the amorphous silicon semiconductor layer and the microcrystalline silicon semiconductor layer are stacked in sequence of p layer-i layer-n layer.

3. The photovoltaic device according to claim 1, wherein the first solar cell comprises a first transparent electrode layer, an amorphous silicon p-type semiconductor layer, an amorphous silicon i-type semiconductor layer, an amorphous silicon n-type semiconductor layer, and a second transparent electrode layer on the first substrate.

4. The photovoltaic device according to claim 1, wherein the second solar cell comprises a third electrode layer, an n-type semiconductor layer, an i-type semiconductor layer, a p-type semiconductor layer, and a fourth transparent electrode layer on the second substrate.

5. The photovoltaic device according to claim 4, wherein the n-type semiconductor layer, i-type semiconductor layer, and p-type semiconductor layer of the second solar cell are the microcrystalline silicon semiconductor layer.

6. The photovoltaic device according to claim 5, wherein the n-type semiconductor layer, i-type semiconductor layer, and p-type semiconductor layer of the second solar cell are a lateral crystallization layer.

7. The photovoltaic device according to claim 4, wherein the third electrode layer is formed of a metal electrode or a metal electrode and a transparent electrode.

8. The photovoltaic device according to claim 3 or 4, wherein the second transparent electrode layer and the fourth transparent electrode layer are connected by means of the junction layer.

9. The photovoltaic device according to claim 1, wherein the junction layer comprises a transparent adhesive.

10. The photovoltaic device according to claim 1, wherein the first substrate and the second substrate are a transparent substrate, respectively.

11. The photovoltaic device according to claim 1, wherein the first solar cell and the second solar cell are connected in series or in parallel.

12. A fabrication method of a photovoltaic device comprising the steps of:
forming an amorphous silicon semiconductor layer; and
forming a semiconductor layer having microcrystalline silicon made by crystallization of the amorphous silicon semiconductor layer.

13. A fabrication method of a photovoltaic device comprising the steps of:
forming a first solar cell having an amorphous silicon semiconductor layer on a first substrate;
forming a second solar cell having a microcrystalline silicon semiconductor layer on a second substrate; and
electrically connecting the first solar cell and the second solar cell by a junction thereof.

14. The method according to claim 13, wherein the electrical connection is a serial connection or a parallel connection.

15. The method according to claim 13, wherein the step of forming the first solar cell sequentially stacks a first transparent electrode layer, an amorphous silicon p-type semiconductor layer, an amorphous silicon i-type semiconductor layer, an amorphous silicon n-type semiconductor layer, and a second transparent electrode layer on the first substrate.

16. The method according to claim 13, wherein the step of forming the second solar cell sequentially stacks a third electrode layer, a microcrystalline silicon n-type semiconductor layer, a microcrystalline silicon i-type semiconductor layer, a microcrystalline silicon p-type semiconductor layer, and a fourth transparent electrode layer on the second substrate.

17. The method according to claim 16, wherein the microcrystalline silicon semiconductor layer is made of the microcrystalline silicon by forming the amorphous silicon semiconductor layer and then crystallizing it.

18. The method according to claim 17, wherein the crystallization method is any one selected from a group consisting of an excimer laser annealing (ELA), a sequential lateral solidification (SLS), a solid phase crystallization (SPC), a metal induced crystallization (MIC), a metal induced lateral crystallization (MILC), a super grain silicon (SGS), a field enhanced-rapid thermal annealing process (FE-RTP), and a continuous grain silicon (CGS) methods.

19. The method according to claim 16, wherein the third electrode layer is formed of a metal electrode or a metal electrode and a transparent electrode.

20. The method according to claim 15 or 16, wherein the second transparent electrode layer and the fourth electrode layer is junctioned by means of a transparent adhesive.
